(19) United States
(12) Patent Application Publication
(10) Pub. No.: US 2019/0245286 A1
(43) Pub. Date: Aug. 8, 2019

(54) PRESSURE ADAPTIVE CONTACT STRUCTURE FOR FLEXIBLE CIRCUIT BOARD

(71) Applicant: ADVANCED FLEXIBLE CIRCUITS CO., LTD., Zhongli City (TW)

(72) Inventors: CHIH-HENG CHUO, BADE CITY (TW); KUO-FU SU, ZHONGLI CITY (TW)

(21) Appl. No.: 16/387,833

(22) Filed: Apr. 18, 2019

Related U.S. Application Data
(62) Division of application No. 16/002,198, filed on Jun. 7, 2018.

(30) Foreign Application Priority Data
Aug. 25, 2017 (TW) 106128919

(51) Int. Cl. H01R 12/65; H01R 12/69; H01R 12/61; G01R 31/28; H05K 1/11; H01R 12/79; H05K 1/02

(52) U.S. Cl. CPC H01R 12/65; H01R 12/69; H01R 12/613; G01R 31/2818; H05K 2201/09445; H01R 12/79; H05K 1/0281; H05K 2201/09409; H05K 1/118

(57) ABSTRACT

A pressure adaptive contact structure for a flexible circuit board is disclosed, in which the flexible circuit board is provided with a weakening portion or a partly surrounding weakening portion between a plurality of first contact pads so that contact surfaces of the plurality of first contact pads are respectively contactable with corresponding ones of contact points to generate contact pressing forces applied to the contact points in a manner that the contact pressing forces are adaptively adjustable by the weakening portion to accommodate height differences between adjacent ones of the first contact pads to prevent the first contact pads from being stretched and pulled with respect to each other.

### REFERENCE TO RELATED APPLICATION

This application is a division of Ser. No. 16/002,198 filed Jun. 7, 2018, currently pending.

### BACKGROUND OF THE INVENTION

1. Field of the Invention

The present invention relates to a contact structure of a flexible circuit board, and in particular to a pressure adaptive contact structure of a flexible circuit board.

2. The Related Arts

Flexible circuit boards are advantageous of being flexible, thin, and light in weight and have been widely used as a flat connection cable or a connection circuit board and have also been used in applications for contact and connection with terminals of flexible circuit boards and rigid circuit boards.

In a known design, to connect a flexible circuit board to contact terminals of a circuit board, a flexible circuit, or a rigid circuit board, a connector or soldering is often used to establish the connection between contact terminals. Such a measure apparently increases parts cost and assembly operation cost of the connector, and is adverse to the requirement of being light, small, and thin for an electronic product. Reduction of fabrication expenditure, saving of device space, and lowering of contact resistance could be made possible by establishing connection of contact terminals between a flexible circuit board and a circuit board, a flexible circuit board, or a rigid circuit board through direct contact therebetween. This could also simplify complexity of signal connection so as to improve signal quality of high frequency signals.

In addition, in the field of circuit testing for all sorts of circuit board, the flexible circuit boards are often used as contact point for electrical tests of circuit boards. In such circuit testing, a flexible circuit board is arranged such that contact pads thereof are set, with the aid of a test fixture, to have contact surfaces in pressing contact with contact terminals of a circuit board to be tested in order to carry out a test on the circuit board to be tested with an electrical testing system.

However, troubles are often encountered in an actual application of the flexible circuit board, due to certain properties of the flexible circuit board, such as flexibility, miniaturization of the contact pads, and slim spacing between adjacent contact pads. In addition, deviation often occurs in respect of the sizes of the contact pads of the flexible circuit board, such as difference of vertical location, difference concerning outside contour, and difference of width, in the fabrication of the contact pads of the flexible circuit board. This leads to stretching caused by stresses generated between adjacent ones of the contact pads so that pressing force, contact resistance, and deviation of contact position may vary among different ones of the contact pads in contact with the contact terminals.

### SUMMARY OF THE INVENTION

In view of the shortcomings of the prior art, an objective of the present invention is to provide a contact structure of a flexible circuit board that shows characteristic of being adaptive to contact pressing force.

A technical solution adapted in the present invention to achieve the above objective is that a weakening portion is formed among a plurality of contact pads of a flexible circuit board such that contact surfaces of the plurality of contact pads are respectively contactable with corresponding ones of contact points to generate contact pressing forces applied to the contact points in a manner that the contact pressing forces are adaptively adjustable by the weakening portion to accommodate height differences between adjacent ones of the contact pads to prevent the contact pads from being stretched and pulled with respect to each other.

In another embodiment of the present invention, a partly surrounding weakening portion is formed in the circumference of each of the contact pads of the flexible circuit board such that contact surfaces of the plurality of contact pads are respectively contactable with corresponding ones of contact points to generate contact pressing forces applied to the contact points in a manner that the contact pressing forces are adaptively adjustable by the partly surrounding weakening portion to accommodate height differences between adjacent ones of the contact pads to prevent the contact pads from being stretched and pulled with respect to each other.

In respect of efficacy, the present invention provides a flexible circuit board that allows for establishment of connection with contact terminals of a circuit board to be contacted, a flexible circuit board, or a rigid circuit board without involving a connector or soldering of the contact terminals. In the present invention, adjacent contact pads are independently and adaptively adjustable of contact pressing forces thereof applied to the corresponding contact points so that stretching or pulling between the adjacent contact pads can be eliminated to thereby effectively overcome the issue of stretching or pulling occurring between adjacent contact pads due to height difference, contour difference, width difference between the adjacent contact pads so as to provide excellent and consistent contact pressing force, contact resistance, and contact position between the contact pads and the corresponding contact points.

### BRIEF DESCRIPTION OF THE DRAWINGS

The present invention will be apparent to those skilled in the art by reading the following description of preferred embodiments of the present invention, with reference to the attached drawings, in which:

FIG. 1 is a plan view showing a first embodiment of the present invention;

FIG. 2 is a schematic view showing the flexible circuit board of FIG. 1 set in a condition of corresponding, in a vertical direction, to a circuit board to be contacted;

FIG. 3A is a cross-sectional view taken along line 3A-3A of FIG. 1;

FIG. 3B is a cross-sectional view showing the flexible circuit board of FIG. 3A set in a condition of corresponding, in a vertical direction, to and in pressing contact with a circuit board to be contacted;

FIGS. 3C-3I are cross-sectional views illustrating various examples of modification of the first embodiment of the present invention;

FIGS. 4A-4F are cross-sectional views illustrating various examples of a second embodiment according to the present invention;

FIGS. 5A-5F are cross-sectional views illustrating various examples of a third embodiment according to the present invention;

FIG. 6 is a plan view showing a fourth embodiment of the present invention;

FIG. 7 is a schematic view showing the flexible circuit board of FIG. 6 set in a condition of corresponding, in a vertical direction, to a circuit board to be contacted; and

FIG. 8 is a plan view showing a fifth embodiment of the present invention.

### DETAILED DESCRIPTION OF THE PREFERRED EMBODIMENTS

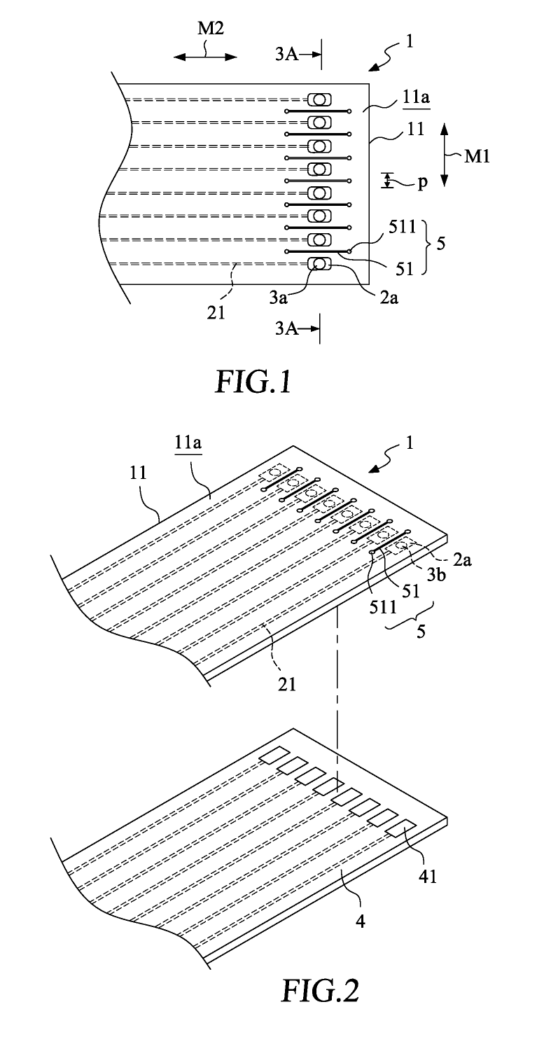

Referring to FIGS. 1 and 2, the present invention provides a flexible circuit board 1 having a first substrate surface 11a on which a plurality of first contact pads 2a are formed and arranged in a row-wise direction M1 such that every two adjacent ones of the first contact pads 2a is isolated from each other by a spacing zone P arranged therebetween. Each of the first contact pads 2a is connected to a conductor line 21 extending therefrom. Each of the first contact pads 2a is combined with a first raised portion 3a that is formed as being raised and projecting from the first contact pads 2a.

The flexible circuit board 1 of the present invention is extended in an extension direction M2 and is applicable to contacting with corresponding ones of contact terminals of a circuit board to be contacted in a contacting operation, and may also be applicable to establishing contact and connection with contact terminals of a flat cable, or between a flat cable and a flexible circuit board or a rigid circuit board, between or with the contact terminals thereof. For example, as shown in FIG. 2, to use the flexible circuit board 1, the flexible circuit board 1 is set in a condition of corresponding, in a vertical direction, to a circuit board to be contacted 4, such that contact surfaces (bottom surfaces) of the first contact pads 2a of the flexible circuit board 1 are in pressing contact with corresponding ones of contact points 41 of the circuit board to be contacted 4 in order to carry out a test.

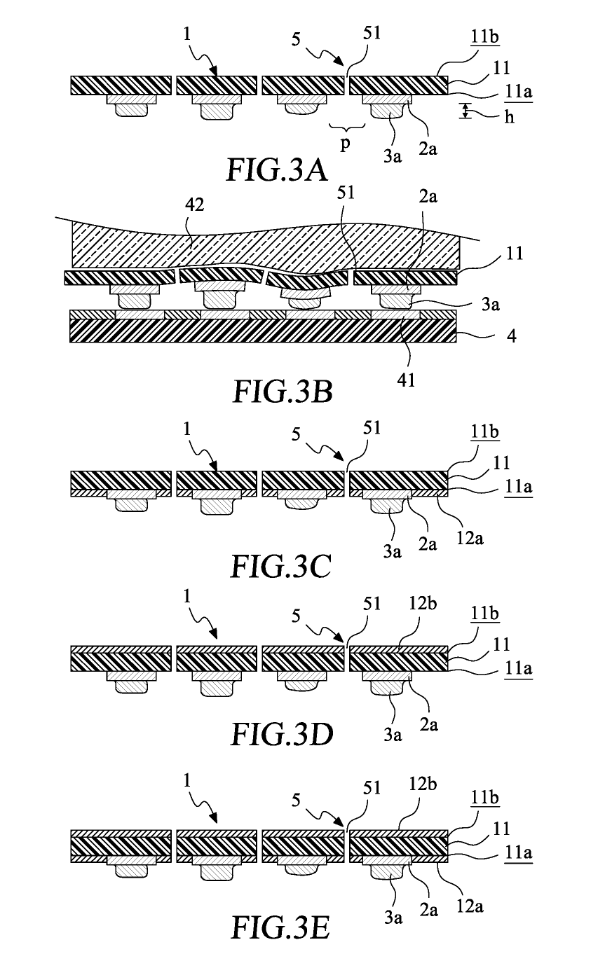

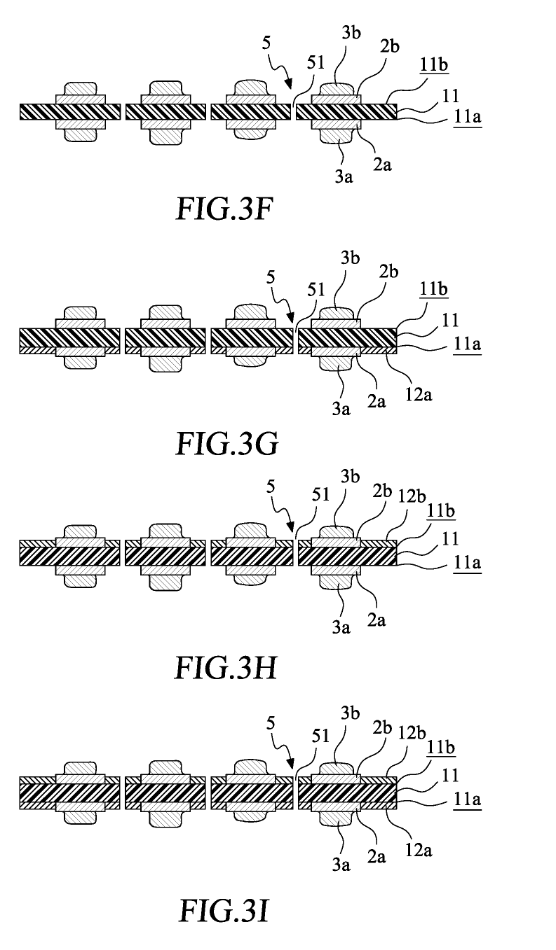

Referring also to FIG. 3A, the present invention is made such that a weakening portion 5 is formed in the spacing zone P between every two adjacent ones of the first contact pads 2a of the flexible circuit board 1. In the instant embodiment, the weakening portion 5 comprises a cutting line 51 formed in a substrate 11 of the flexible circuit board 1 such that the cutting line 51 cuts through and divides the spacing zone P between the two adjacent first contact pads 2a. Further, each of the cutting lines 51 has two opposite ends, each formed with a tear protection section 511.

Referring also to FIG. 3B, when an external force is applied from a top side of the flexible circuit board 1 and is transmitted through a cushion pad 42 to the flexible circuit board 1, each of the weakening portions 5 of the flexible circuit board 1 allows the contact surfaces of the first contact pads 2a to separately and individually contact and press against and contact the contact points 41 so that even though a height difference h may exist between two adjacent ones of the first contact pads 2a, contact forces of the two adjacent first contact pads 2a with the corresponding contact points 41 may be adaptively adjusted for each individual one of the first contact pads 2a to eliminate undesired stretching and pulling that might be caused between the adjacent first contact pads 2a due to the height difference.

FIGS. 3C-3I show cross-sectional views of various examples of modification of the first embodiment of the present invention. For consistency, components/parts of the modified examples that are identical or similar to those of the first embodiment would bear the same reference numerals.

FIG. 3C shows the first substrate surface 11a of the substrate 11 of the flexible circuit board 1 shown in FIG. 3A is further formed with a first protection layer 12a.

FIG. 3D shows a second substrate surface 11b of the substrate 11 of the flexible circuit board 1 shown in FIG. 3A is formed with multiple second contact pads 2b.

FIG. 3E shows the first substrate surface 11a of the substrate 11 of the flexible circuit board 1 shown in FIG. 3A is further formed with a first protection layer 12a, and a second substrate surface 11b of the substrate 11 is formed with a second contact pad 2b.

FIG. 3F shows the second substrate surface 11b of the substrate 11 of the flexible circuit board 1 shown in FIG. 3A is further formed with multiple second contact pads 2b and second raised portions 3b respectively corresponding to the first contact pads 2a and the first raised portions 3a.

FIG. 3G shows the second substrate surface 11b of the substrate 11 of the flexible circuit board 1 shown in FIG. 3C is further formed with multiple second contact pads 2b and second raised portions 3b respectively corresponding to the first contact pads 2a and the first raised portions 3a.

FIG. 3H shows the second substrate surface 11b of the substrate 11 of the flexible circuit board 1 shown in FIG. 3D is further formed with multiple second contact pads 2b and second raised portions 3b respectively corresponding to the first contact pads 2a and the first raised portions 3a.

FIG. 3I shows the second substrate surface 11b of the substrate 11 of the flexible circuit board 1 shown in FIG. 3E is further formed with multiple second contact pads 2b and second raised portions 3b respectively corresponding to the first contact pads 2a and the first raised portions 3a.

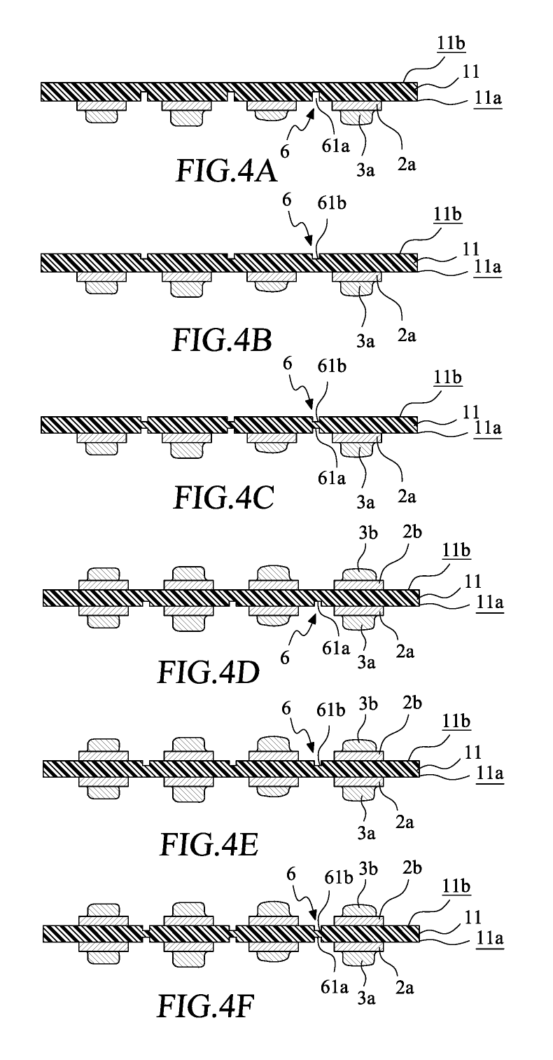

FIGS. 4A-4F are cross-sectional views illustrating various examples of a second embodiment according to the present invention, in which FIG. 4A illustrates, in the instant embodiment, a weakening portion 6 comprises multiple first recesses 61a formed in the first substrate surface 11a of the substrate 11.

FIG. 4B illustrates the second embodiment of the present invention comprises multiple second recesses 61b formed in the second substrate surface 11b of the substrate 11.

FIG. 4C illustrates the second embodiment of the present invention comprises multiple first recess 61a formed in the first substrate surface 11a of the substrate 11 and multiple second recesses 61b formed in the second substrate surface 11b of the substrate 11.

FIG. 4D illustrates the second substrate surface 11b of the substrate 11 of the flexible circuit board 1 shown in FIG. 4A is further formed with multiple second contact pads 2b and second raised portions 3b respectively corresponding to the first contact pads 2a and first raised portions 3a.

FIG. 4E illustrates the second substrate surface 11b of the substrate 11 of the flexible circuit board 1 shown in FIG. 4B is further formed with multiple second contact pads 2b and second raised portions 3b respectively corresponding to the first contact pads 2a and first raised portions 3a.

FIG. 4F illustrates the second substrate surface 11b of the substrate 11 of the flexible circuit board 1 shown in FIG. 4C is further formed with multiple second contact pads 2b and second raised portions 3b respectively corresponding to the first contact pads 2a and first raised portions 3a.

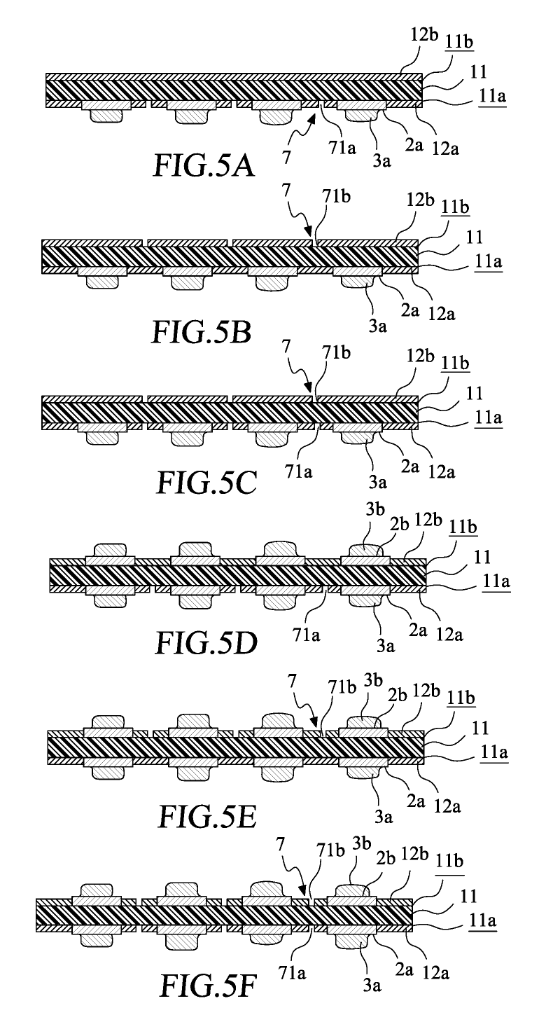

FIGS. 5A-5F are cross-sectional views illustrating various examples of a third embodiment according to the present invention. In the instant embodiment, the substrate 11 comprises a first protection layer 12a formed on the first substrate surface 11a and a second protection layer 12b formed on the second substrate surface 11b.

FIG. 5A illustrates in the third embodiment of the present invention, the weakening portion 7 comprises multiple first cut notches 71a formed in the first protection layer 12a.

FIG. 5B illustrates in the third embodiment of the present invention, the weakening portion 7 comprises multiple second cut notches 71b formed in the second protection layer 12b.

FIG. 5C illustrates in the third embodiment of the present invention, the weakening portion 7 comprises multiple first cut notches 71a formed in the first protection layer 12a and multiple second cut notches 71b formed in the second protection layer 12b.

FIG. 5D illustrates the second substrate surface 11b of the substrate 11 of the flexible circuit board 1 shown in FIG. 5A is further formed with multiple second contact pads 2b and second raised portions 3b respectively corresponding to the first contact pads 2a and first raised portions 3a.

FIG. 5E illustrates the second substrate surface 11b of the substrate 11 of the flexible circuit board 1 shown in FIG. 5B is further formed with multiple second contact pads 2b and second raised portions 3b respectively corresponding to the first contact pads 2a and first raised portions 3a.

FIG. 5F illustrates the second substrate surface 11b of the substrate 11 of the flexible circuit board 1 shown in FIG. 5C is further formed with multiple second contact pads 2b and second raised portions 3b respectively corresponding to the first contact pads 2a and first raised portions 3a.

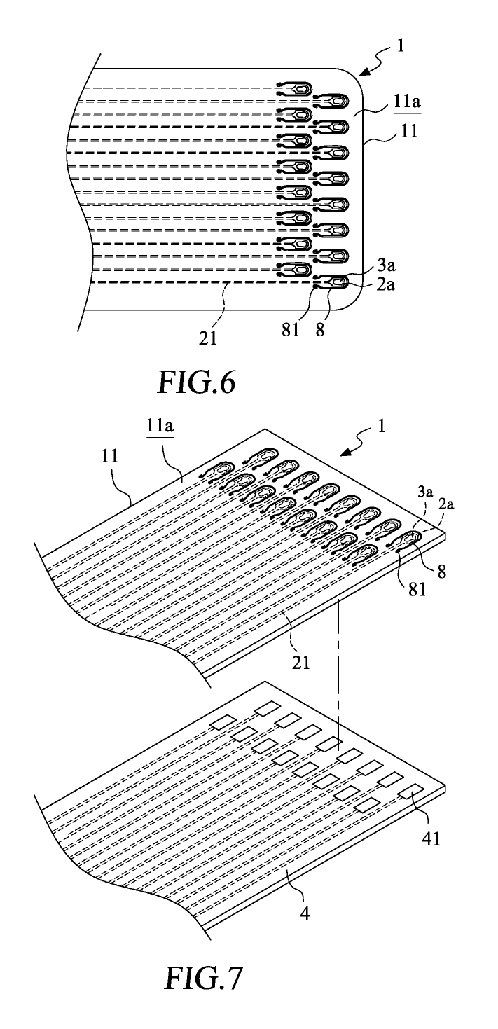

FIG. 6 is a plan view showing a fourth embodiment of the present invention. The instant embodiment similarly comprises a plurality of combinations of first contact pads 2a and first raised portions 3a that are provided on the first substrate surface 11a of a flexible circuit board 1 and spaced from each other. As shown in FIG. 7, to use, the flexible circuit board 1 is set in a condition of corresponding, in a vertical direction, to a circuit board to be contacted 4, such that contact surfaces (bottom surfaces) of the first contact pads 2a of the flexible circuit board 1 are in pressing contact with corresponding ones of contact points 41 of the circuit board to be contacted 4 in order to carry out a test.

The fourth embodiment of the present invention is structured to form a weakening portion 8 to partly surround a circumference of each of the first contact pads 2a of the flexible circuit board 1 so that when the contact surfaces of the plurality of first contact pads 2a are set in pressing contact with the corresponding ones of the contact points 41, the partly surrounding weakening portion 8 provide adaptive adjustment of the contact pressing forces that the adjacent ones of the first contact pads 2a applying to the contact points to adapt various height differences between every two adjacent ones of the first contact pads 2a so as to eliminate undesired stretching and pulling occurring between the adjacent first contact pads 2a. Further, the second substrate surface 11b of the substrate 11 of the flexible circuit board 1 may also be formed with multiple second contact pads 2b and second raised portion 3b respectively corresponding to the first contact pads 2a and the first raised portions 3a.

The partly surrounding weakening portion 8 may comprise a cutting line as shown in FIGS. 3A-3I such that the cutting line cuts and divides a part of the substrate along a circumference of each of the first contact pads 2a. The partly surrounding weakening portion 8 may be provided, on each end thereof, with a tear protection section 81. Alternatively, similar to other embodiments discussed previously, the partly surrounding weakening portion 8 may comprise a recess or a notch, while the flexible circuit board 1 can be simply a substrate or a substrate combined with one or more protective layers.

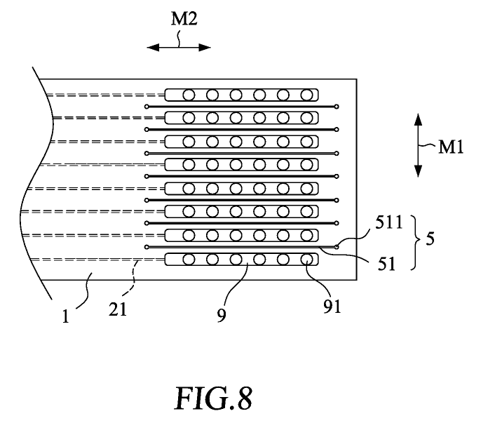

FIG. 8 is a plan view showing a fifth embodiment of the present invention. In the instant embodiment, a flexible circuit board 1 is provided, on a surface thereof, with a plurality of extended contact pads 9 that are isolated from each other and arrayed raised portions 91. Each of the extended contact pads 9 is connected with a conductor line 21 extending therefrom. The instant embodiment is structured to form a weakening portion 5 between every two adjacent ones of the extended contact pads 9 of the flexible circuit board 1. The weakening portion 5 can be a cutting line 51, such that the cutting line 51 cuts and divides a portion of the substrate between the adjacent ones of the extended contact pads 9. The cutting line 51 may be formed, at each end thereof, with a tear protection section 511. Alternatively, similar to embodiments discussed previously, the weakening portion 5 may comprise a recess or a notch, while the flexible circuit board 1 can be simply a substrate or a substrate combined with one or more protective layers.

Although the present invention has been described with reference to the preferred embodiments thereof, it is apparent to those skilled in the art that a variety of modifications and changes may be made without departing from the scope of the present invention which is intended to be defined by the appended claims.

What is claimed is:

1. A contact structure for a flexible circuit board, the flexible circuit board including a plurality of first contact pads formed on a substrate of the flexible circuit board spaced from each other, a spacing zone arranged between adjacent ones of the plurality of first contact pads, the contact structure comprising:
at least one protection layer formed on the substrate; and
a plurality of partly surrounding weakened portions formed in the spacing zone between adjacent ones of the first contact pads, the partly surrounding weakened portions partly surrounding a circumference of each of the first contact pads respectively, contact surfaces of the plurality of first contact pads respectively maintaining contact with corresponding contact points of a contacting circuit board in adaptively adjustable manner to accommodate height differences between adjacent ones of the first contact pads, the partly surrounding weakened portions preventing the flexible circuit board about the first contact pads from being stretched and pulled.

2. The contact structure according to claim 1, wherein the plurality of first contact pads are each provided with a first raised portion that is formed on and raised and projecting from the first contact pad.

3. The contact structure according to claim 1, further comprising a plurality of second contact pads, which are formed a surface of the substrate of the flexible circuit board that is opposite to the plurality of first contact pads.

4. The contact structure according to claim 3, wherein the plurality of second contact pads are each provided with a second raised portion that is formed on and raised and projecting from the second contact pad.

5. The contact structure according to claim 1, wherein the contacting circuit board is one of a circuit flat cable, a flexible circuit board, and a rigid circuit board.

6. The contact structure according to claim 1, wherein each of the partly surrounding weakened portions defines a cutting line extending through both the substrate and the protection layer to be peripherally bounded thereby.

7. The contact structure according to claim 6, wherein ends of the cutting line are each formed with a tear protection section.
